(19) United States
(12) Patent Application Publication
(10) Pub. No.: US 2025/0301733 A1
(43) Pub. Date: Sep. 25, 2025

(54) SEMICONDUCTOR SOURCE/DRAIN AND CONTACT

(71) Applicant: INTERNATIONAL BUSINESS MACHINES CORPORATION, ARMONK, NY (US)

(72) Inventors: Jidong Huang, Rexford, NY (US); Ruilong Xie, Niskayuna, NY (US); Oleg Gluschenkov, Tannersville, NY (US); Jingyun Zhang, Albany, NY (US)

(21) Appl. No.: 18/615,216

(22) Filed: Mar. 25, 2024

(51) Int. Cl. H01L 29/08; H01L 29/06; H01L 29/161; H01L 29/40; H01L 29/417; H01L 29/423; H01L 29/66; H01L 29/775

(52) U.S. Cl. CPC H10D 62/151; H10D 30/014; H10D 30/43; H10D 30/6729; H10D 30/6735; H10D 62/121; H10D 62/832; H10D 64/01

(57) ABSTRACT

A semiconductor structure includes a wafer, a first source/drain (S/D) extending from the wafer, and a first contact connected to the first S/D. The first S/D includes a first component in direct contact with the wafer and the first contact, the first component having a first germanium content, and a second component in direct contact with the first contact, the second component having a second germanium content. The second germanium content is higher than the first germanium content.

### BACKGROUND

The present disclosure relates to semiconductor devices, and more specifically, to source/drains and their electrical contacts in an integrated circuit.

Field-effect transistors (“FETs”) use an electric field effect to control current flow within a semiconductor device. Specifically, FETs may use the electric charge of their gates to affect and control the current flow through a channel. The performance of FETs can be affected by the quality of their electrical connections, for example, due to needless electrical resistance in the flowpath. In addition, the source/drain of a p-channel FET (pFET) can react slightly differently to manufacturing processes than the source/drain of an n-channel FET (nFET). This can also create a performance differential between the different types of FETs.

### SUMMARY

In one embodiment of the present disclosure, a semiconductor structure includes a wafer, a first source/drain (S/D) extending from the wafer, and a first contact connected to the first S/D. The first S/D includes a first component in direct contact with the wafer and the first contact, the first component having a first germanium content, and a second component in direct contact with the first contact, the second component having a second germanium content. The second germanium content is higher than the first germanium content.

In one embodiment of the present disclosure, a semiconductor structure includes a wafer, a first S/D extending from the wafer, and a first contact connected to the first S/D. The first S/D includes a first component in direct contact with the wafer and the first contact, and a second component in direct contact with the first contact. The first contact extends along two first opposing sides of the second component.

In one embodiment of the present disclosure, a method of manufacturing a semiconductor structure includes providing an intermediary semiconductor structure that includes a plurality of spacers and a first component of a first S/D in direct contact with two of the plurality of spacers. The method further includes forming a liner layer on the plurality of spacers and on the first S/D, removing a portion of the liner layer in a region for a second S/D, forming the second S/D, forming an insulator layer on a remaining portion of the liner layer and on the second S/D, forming a first canyon to expose the first component, forming a second component of the first S/D on the first component, forming a second canyon to expose the second S/D, removing an exposed portion of the liner layer while a covered portion of the liner layer remains, and forming a first electrically conductive contact in the first canyon and a second electrically conductive contact in the second canyon.

### BRIEF DESCRIPTION OF THE DRAWINGS

FIGS. 1A, 1B, and 1C are cross-section views of a semiconductor structure, in accordance with embodiments of the present disclosure.

FIG. 1D is a schematic top view of a semiconductor structure, in accordance with embodiments of the present disclosure.

FIG. 2 is a flowchart of a method of manufacturing the semiconductor structure of FIG. 1, in accordance with an embodiment of the present disclosure.

FIGS. 3A, 3B, 3C, 3D, 3E, 3F, 3G, 3H, and 3I are a series of cross-section views of stages in a manufacture of the semiconductor structure according to the method of FIG. 2, in accordance with an embodiment of the present disclosure.

### DETAILED DESCRIPTION

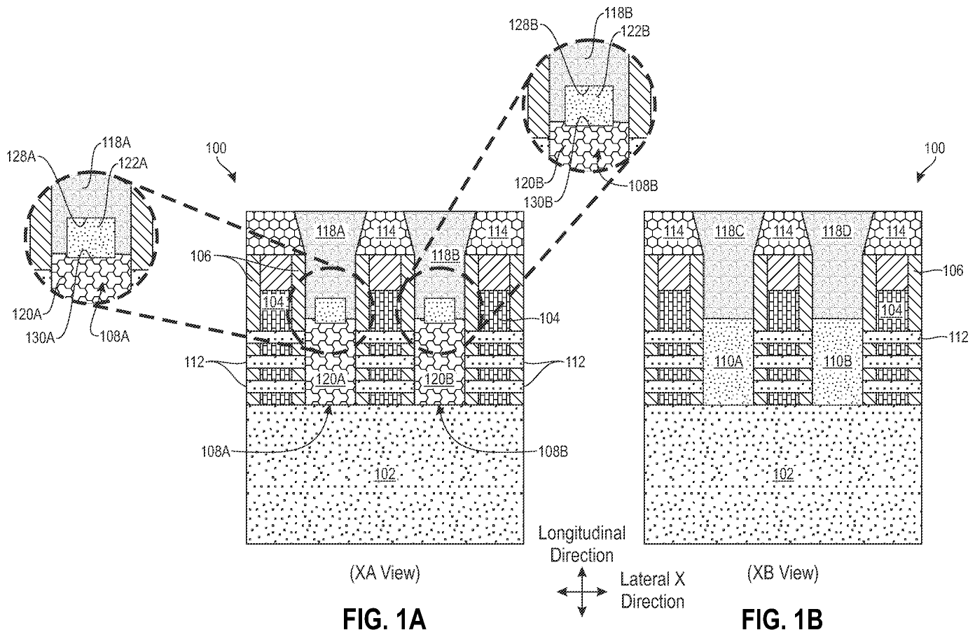

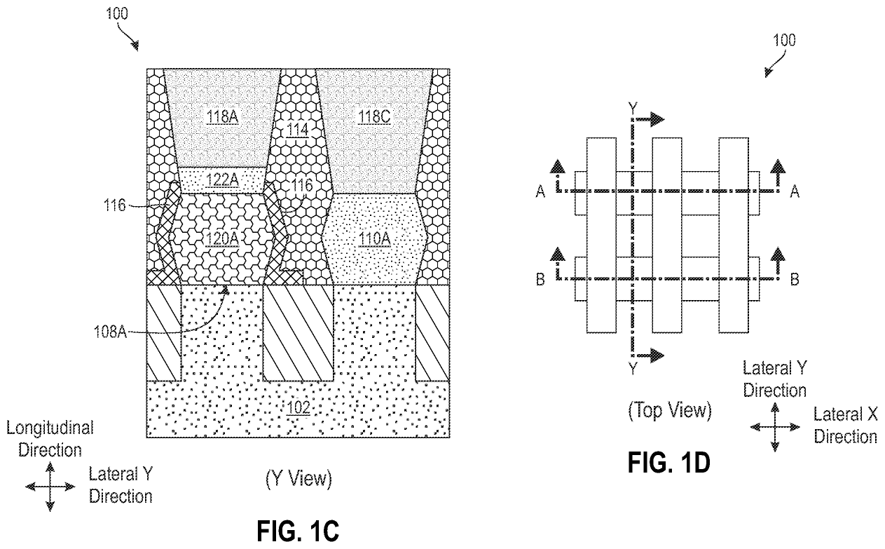

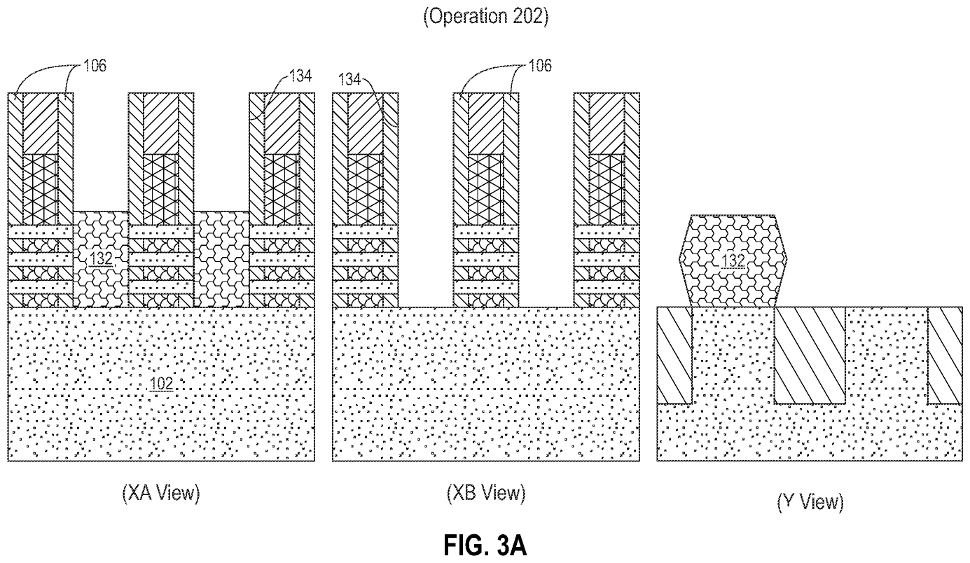

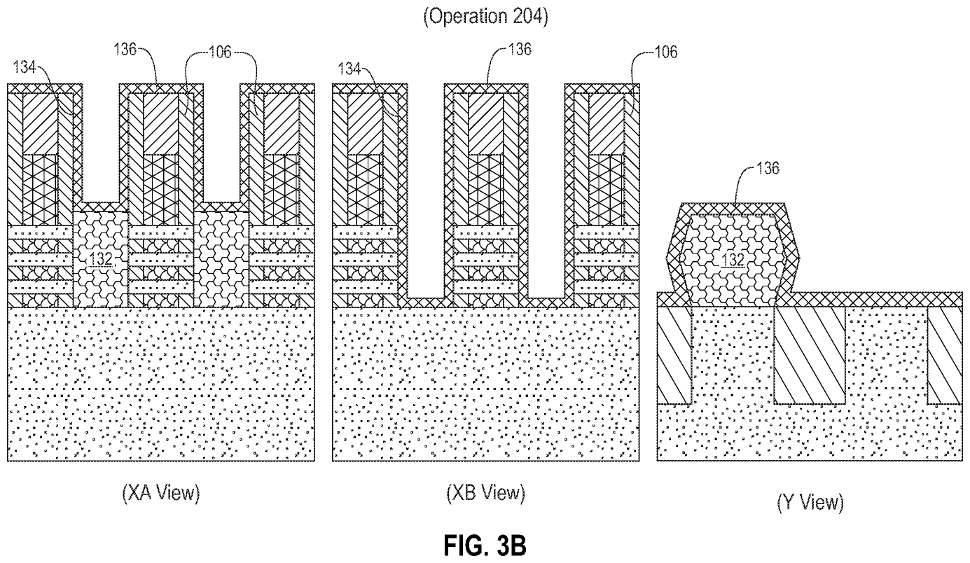

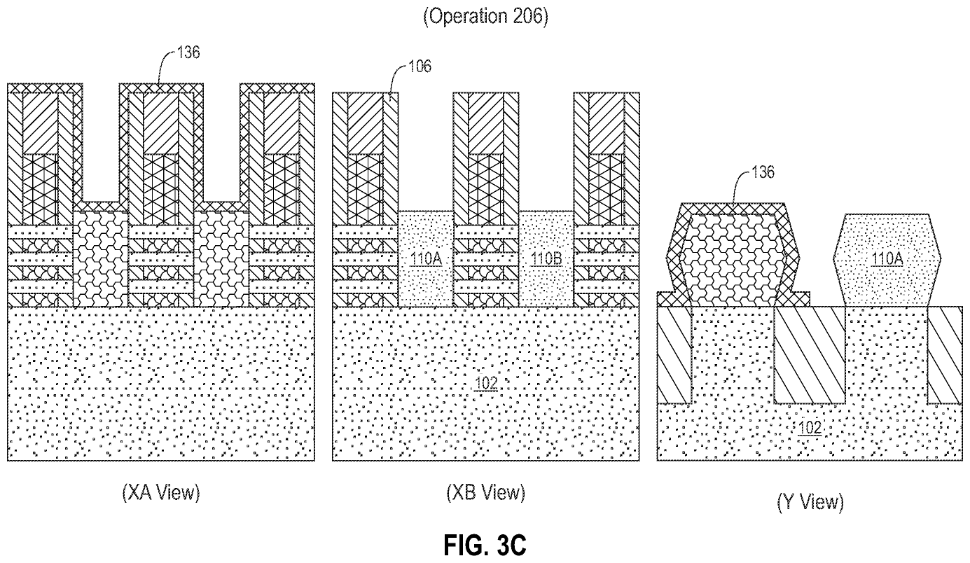

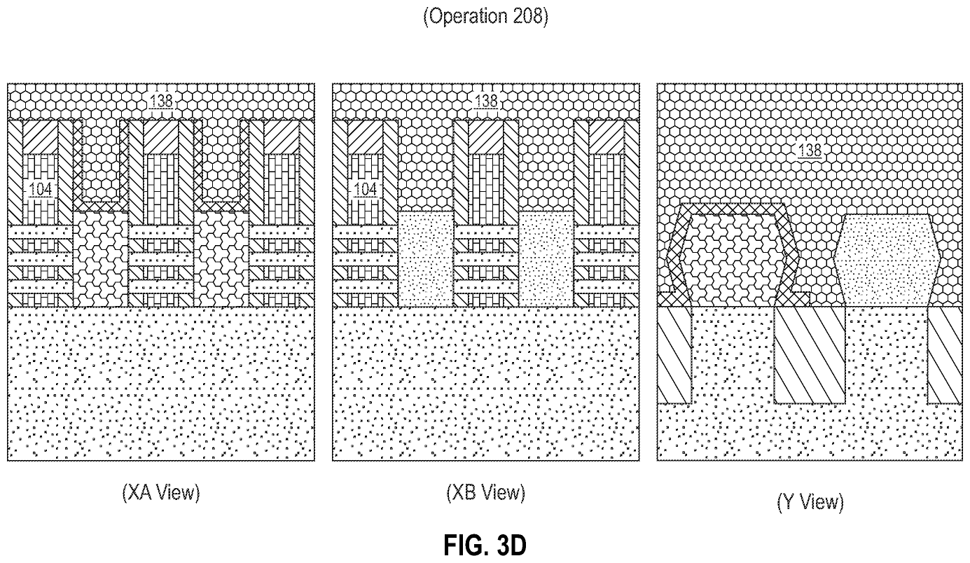

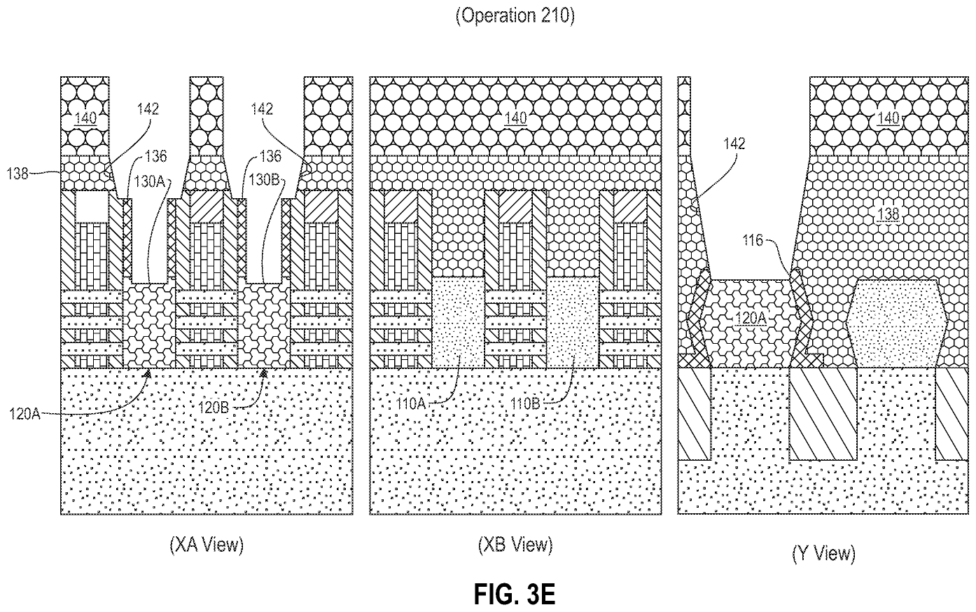

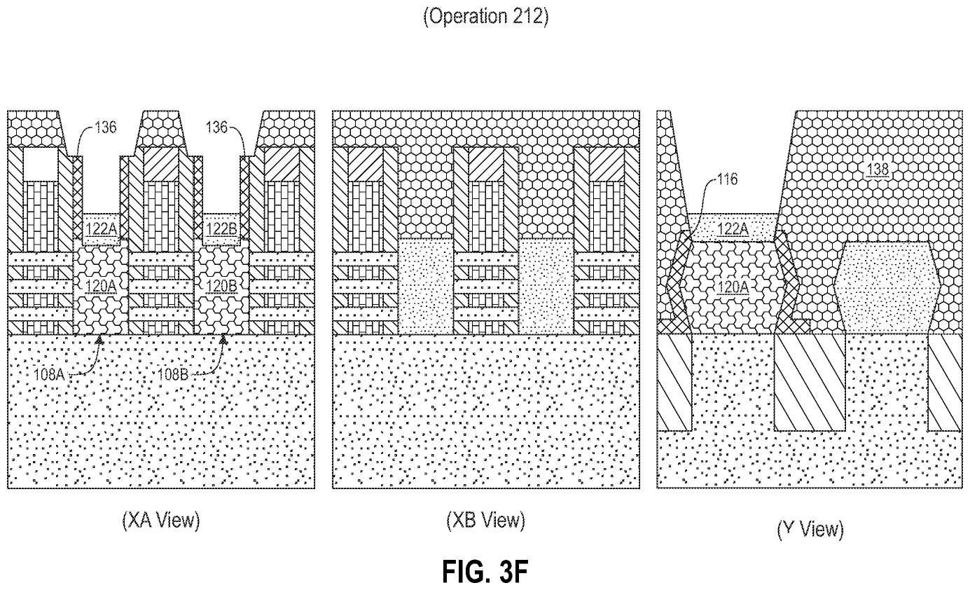

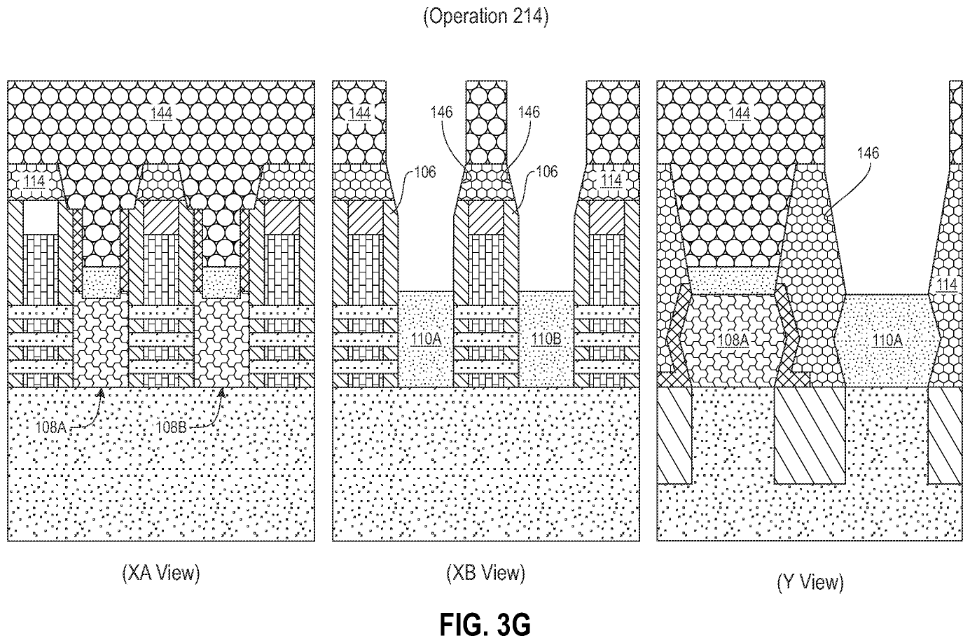

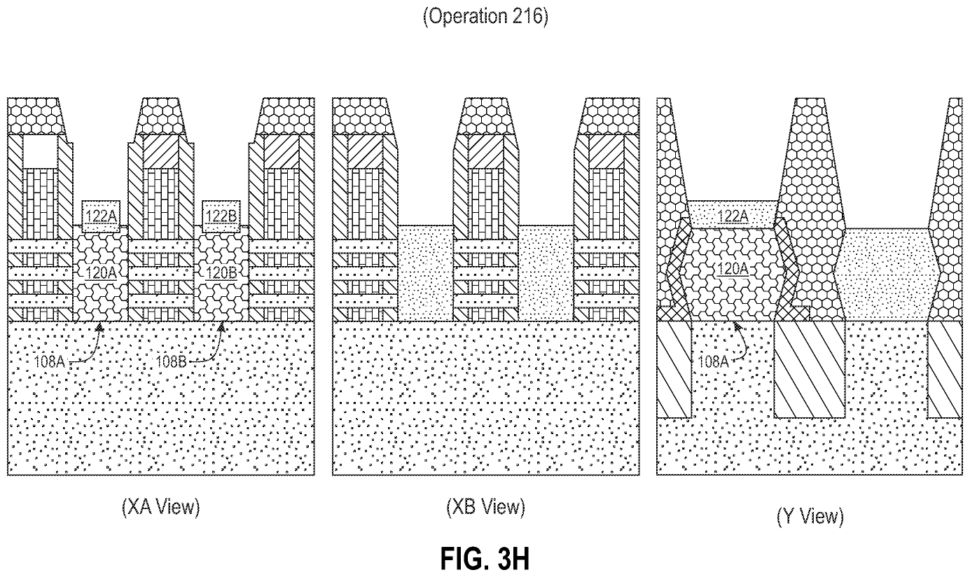

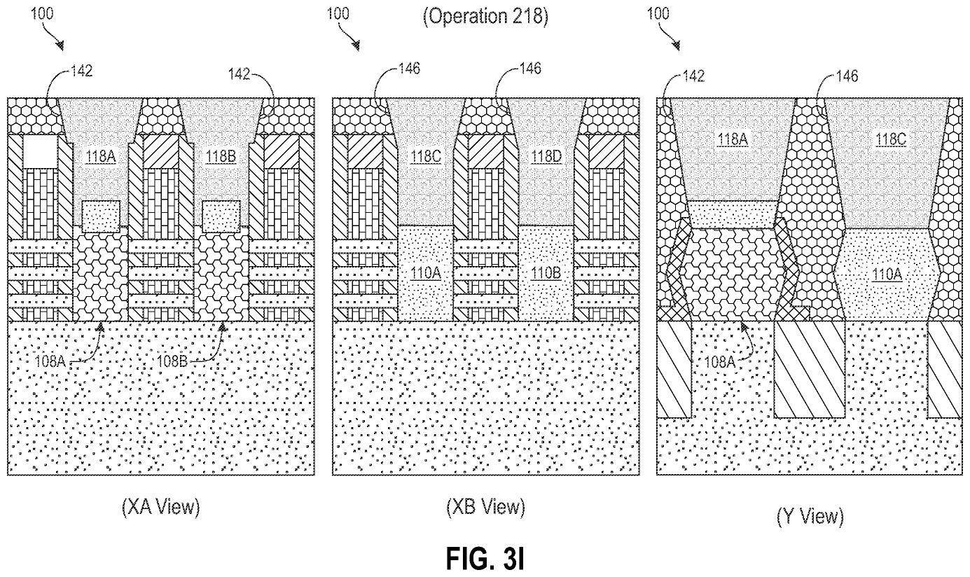

FIGS. 1A, 1B, and 1C are cross-section views of semiconductor structure 100, and FIG. 1D is a schematic top view of semiconductor structure 100. FIG. 1A is an “XA” view, the orientation and location of which is indicated by line A-A in FIG. 1D. FIG. 1B is an “XB” view, the orientation and location of which is indicated by line B-B in FIG. 1D. FIG. 1C is a “Y” view, the orientation and location of which is indicated by line Y-Y in FIG. 1D. The schematic top view of FIG. 1D provides a frame of reference for FIGS. 3A-3I as well. It should be noted that there are components and/or features in the Figures that occur in multiple locations, but, for the sake of simplicity, only some (or one) of them may be labeled in a given Figure. However, the Figures are drawn such that a person having ordinary skill in the art would understand where the other occurrences are.

In the illustrated embodiment, semiconductor structure 100 extends laterally (i.e., left-and-right as depicted in FIGS. 1A-1C) with wafer 102 as the base (e.g., a silicon substrate that is part of the front-end-of-line (FEOL) of semiconductor structure 100). The wafer 102 can include various useful structures and devices that are compatible with forming semiconductor structure 100. The surface of wafer 102 that is in direct contact with the semiconductor stricture 100 can be semiconducting (e.g., a crystalline silicon surface), conducting (e.g., formed by embedded metallic elements), or electrically insulating (e.g., formed by an amorphous insulator such as silicon oxide or nitride). Longitudinally above (vertically as depicted in FIGS. 1A-1C) wafer 102 are other components of semiconductor structure 100. For example, gates 104 and spacers 106 extend longitudinally from wafer 102. For another example, pFET epitaxial source/drains (pS/Ds) 108A-108B (collectively “pS/Ds 108”) and nFET epitaxial source/drains (nS/Ds) 110A-110B (collectively “nS/Ds 110”) extend longitudinally from wafer 102 between and in direct contact with spacers 106, respectively. pS/Ds 108 and nS/Ds 110 are separated from gates 104 by spacers 106 and nanosheets 112. The epitaxial nature of pS/Ds 108 and nS/Ds 110 can be achieved by templating their respective crystalline structure from either the wafer 102 crystalline surface or the crystalline sidewall surfaces of nanosheets 112. The pS/Ds 108 and nS/Ds 110, and gates 104 can be electrically insulated from semiconducting or conducting elements of wafer 102. The electrical insulation can be achieved by disposing dielectrics therebetween and/or by junction isolation. Thus, semiconductor structure 100 includes nanosheet transistors (not labeled for the sake of simplicity).

In the illustrated embodiment, insulator 114 electrically separates selected electrically conductive and/or semiconductive components from each other. For example, as shown in FIG. 1C, insulator 114 is positioned between pS/D 108A and nS/D 110A which are otherwise adjacent to each other (i.e., there are no other S/Ds between them). In addition, a liner 116 extends along at least two of the opposing sides of pS/Ds 108, whereas nS/Ds 110 lack a liner such as liner 116 (so nS/Ds 110 are in direct contact with insulator 114 on at least two of the opposing sides). Spacers 106, insulator 114 and liner 116 are electrically insulative and can be comprised of a medium dielectric constant material (a.k.a. mid-κ), such as, for example, silicon carbide (SiC), silicon nitride (SiN), silicon dioxide (SiO2), silicon nitride carbide (SiNC), tetraethyl orthosilicate (TEOS), silicon oxycarbide (SiCOx), silicon oxycarbonitride (SiCNO), or siliconboron carbonitride (SiBCN), or a mixture of one or more of the aforementioned materials. Spacers 106, insulator 114, and liner 116 can be comprised of the same material or different materials, although advantages to using particular materials and combinations of materials will be discussed later.

For semiconductor structure 100 to function as intended, electrical connections are made, for example, with pS/Ds 108 and nS/Ds 110. In the illustrated embodiment, contacts 118A-118D (collectively “contacts 118) are middle-of-line (MOL) structures that extend upwards to electrically connect pS/Ds 108 and nS/Ds 110 to back-end-of-line (BEOL) components (not shown), such as, for example, interconnects. The top side of pS/D 108A and the bottom side of contact 118A are in direct contact with each other to form an electrical connection, the top side of pS/D 108B and the bottom side of contact 118B are in direct contact with each other to form an electrical connection, the top side of nS/D 110A and the bottom side of contact 118C are in direct contact with each other to form an electrical connection, and the top side of nS/D 110B and the bottom side of contact 118D are in direct contact with each other to form an electrical connection. Since the top side of nS/D 110B is planar and the bottom side of contact 118D is planar, the interface therebetween is solely planar. Note that the term “planar” in this context is not limited to merely flat surfaces. Instead, “planar” can mean a surface with some curvature to it (e.g., a V-shape, U-shape, or other complex shape such as a saddle-shape) but lacks the discontinuous nature that the interface between pS/Ds 108 and contacts 118 have due to their recesses. The signal transmission components (e.g., contacts 118) are comprised of an electrically conductive material, such as elemental metal or metallic compound (e.g., titanium silicide (TiSi), titanium germanosilicide (TiSiGe), titanium nitride (TiN), cobalt (Co), ruthenium (Ru), molybdenum (Mo), or tungsten (W)). The signal transmission components can be comprised of the same material or different materials, and a material can appear in multiple components. The electrical resistivity of signal transmission elements is significantly lower than that of epitaxial S/Ds 108/110 and typically ranges from about 10 microohm centimeters (μOhm-cm) to about 100 μOhm-cm.

In the illustrated embodiment, pS/Ds 108 are comprised of two semiconducting components-primary epitaxial materials (PEMs) 120 (i.e., PEM 120A and PEM 120B, respectively) and intermediate epitaxial materials (IEMs) 122 (i.e., IEM 122A and IEM 122B, respectively). PEMs 120 have a lower germanium (Ge) content than IEMs 122. In some embodiments, the Ge content of PEMs 120 is 0-50%, and in some embodiments, the Ge content of PEMs 120 is 20-35%. In some embodiments, the Ge content of IEMs 122 is 45-100%, and in some embodiments, there are one or more intermediary layers (not shown) between PEMs 120 and IEMs 122 that have Ge content values between that of PEMs 120 and IEMs 122 to minimize dislocation formation. Ge content in PEMs 120 and IEMs 122 may affect the ability to activate p-type dopants in these semiconducting materials and their bulk resistivity. Boron activation peaks at an intermediate Ge content of about 50% and a further increase in Ge content leads to a degraded hole mobility and increased bulk resistivity. Gallium (Ga) activation increases with Ge content peaking for pure Ge but an excessive amount of Ga also leads to a degraded hole mobility and an increased bulk resistivity. Accordingly, the lowest bulk resistivity is achieved in a boron doped SiGe at an intermediate Ge content of 30-60% and typically ranges from 300 μOhm-cm to 500 μOhm-cm while the highest concentration of holes, typically above 1e+21 cm³, is achieved in SiGe doped with a mixture of B and Ga at a high Ge content of above 60%. Ge content in PEMs 120 and IEMs 122 may also affect the Schottky barrier height in semiconductor-metal contacts modulating specific contact resistivity. A higher Ge content results in a smaller Schottky barrier height. The specific contact resistivity is lowered by increasing the hole concentration in a vicinity of the contact interface and reducing Schottky barrier height. Unlike the bulk resistivity, the specific contact resistivity does not depend on the hole mobility.

Having different Ge contents between PEMs 120 and IEMs 122 can confer particular benefits. For example, a higher Ge content reduces electrical contact resistance with contacts 118, which can increase the performance of the pFETs when compared to a configuration with only a lower Ge content. For another example, a lower Ge content allows for easier growth and patterning when compared to a higher Ge content, which can be advantageous since PEMs 120 are the majority component of pS/Ds 108. In addition, the bulk resistance of PEMs 120 is reduced at lower/intermediate Ge content. In some embodiments, the longitudinal height of IEMs 122 is no more than half of the longitudinal height of PEMs 120, and the top of IEMs 122 will not be longitudinally higher than the tops of gates 104. In other embodiments, the longitudinal height of IEMs 122 is selected to prevent severe current crowding effects as detailed below. On the other hand, each of nS/Ds 110 is composed of a single monolith of epitaxial material. In some embodiments, nS/Ds 110 are the same as PEMs 120 with respect to the material(s) included therein.

In the illustrated embodiment, PEMs 120 are in direct contact with wafer 102, whereas IEMs 122 are separated from wafer 102. However, both PEMs 120 and IEMs 122 are in direct contact with contacts 118, respectively. IEMs 122 can be positioned in recesses in at least one of contacts 118 and PEMs 120, although, as shown in FIG. 1A, both contacts 118 and PEMs 120 include recesses 128 (i.e., recesses 128A and 128B) and recesses 130 (i.e., recesses 130A and 130B), respectively. As indicated by FIG. 1C, recesses 128 and 130 extend orthogonally to the direction that liner 116 extends, so the opposing sides of IEMs 122 that contact recesses 128 and 130 are different from the opposing sides that contact liner 116. This is why recesses 128 and 130 are visible in FIG. 1A and not in FIG. 1C, but liner 116 is visible in FIG. 1C and not in FIG. 1A. Due to recesses 128 and 130, respectively, the top surfaces of PEMs 120 are U-shaped, and the bottom surfaces of contacts 118 are inverted-U-shaped. This means that contacts 118 and PEMs 120 wrap around and extend along at least two of the opposing sides of IEMs 122.

In the illustrated embodiment, the longitudinal depth and lateral width of recesses 128 and the lateral width of IEMs 122 are selected to prevent severe current crowding effects in narrow channels of contacts 118 that wrap around IEMs 122 and in the IEMs 122 themselves. Severe current crowding arises when the longitudinal bulk resistance of these elements exceeds the interfacial contact resistance between them. Advantageously, the lateral width of recesses 128 is made significantly smaller than the lateral width of IEMs 122 to minimize the current crowding effect in IEMs 122 (in a higher resistivity material) while balancing the current crowding effect in narrow recess channel filled with contact 118 (in a lower resistivity material). In one example, the lateral width of recesses 128 is at least 4 times smaller than the lateral width of IEMs 122. In another example, the lateral width of recesses 128 is selected to match the longitudinal bulk resistance of IEMs 122 to that of each of recess channels 128 filled with the contact material 118. The longitudinal depth of recesses 128 and the related longitudinal height of IEMs 122 are limited by the current crowding effect in IEMs 122 and should not exceed twice the lateral width of IEMs 122. In one example, the specific contact resistivity between IEMs 122 and the contact material 118 is at or below 7e−10 Ohm-cm² and the longitudinal depth of recesses 128 and the related longitudinal height of IEMs 122 does not exceed the lateral width of IEMs 122 in order to avoid severe current crowding effects. Furthermore, when compared to a solely planar interface (e.g., nS/D 110B and contact 118D), the recessing of IEMs 122 into contacts 118 and PEMs 120 increases the area of surface contact between IEMs 122 and contacts 118 and between IEMs 122 and PEMs 120. In the absence of severe current crowding effects, this increase in contact area reduces electrical contact resistance between IEMs 122 and contacts 118 and between IEMs 122 and PEMs 120 when compared to solely planar interfaces that lack recesses. As stated above, reducing electrical contact resistance increases the performance of the pFETs, which boosts the performance of semiconductor structure 100.

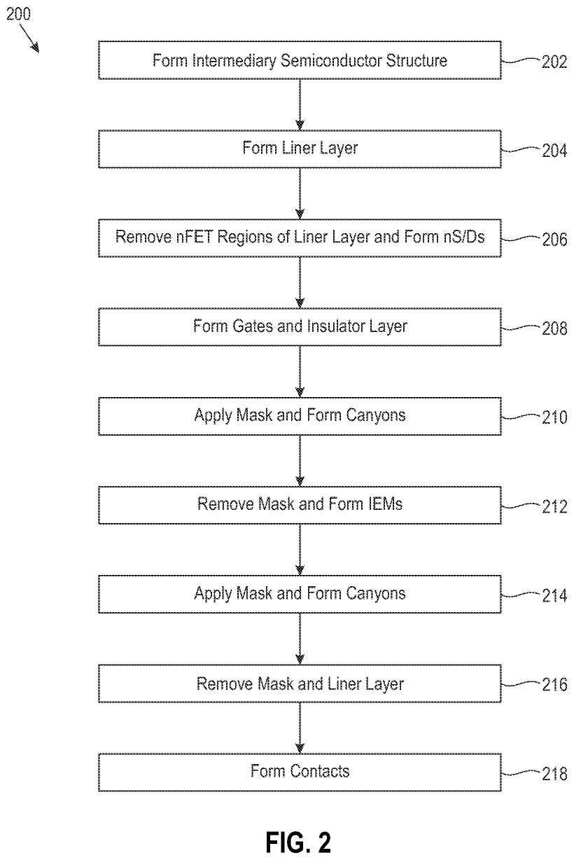

FIG. 2 is a flowchart of method 200 of manufacturing semiconductor structure 100. FIGS. 3A-3I are a series of cross-section views of stages in a manufacture of the semiconductor structure according to method 200. The results of each operation in method 200 are illustrated in a respective one of FIGS. 3A-3I, so FIGS. 2 and 3A-3I will be discussed in conjunction with one another. In addition, during this discussion, references may be made to features of semiconductor structure 100 (shown in FIGS. 1A-1D), however, some features may be omitted for the sake of simplicity.

In the illustrated embodiment, method 200 begins at operation 202 in which an intermediary version of the semiconductor structure is formed, which includes spacers 106 and primary epitaxial layer (PEL) 132. As shown in FIG. 3A, spacers 106 laterally bound cavities 134 (where pS/Ds 108, nS/Ds 110, and contacts 118 will eventually be formed), so pS/Ds 108 and nS/Ds 110 will be self-aligned with their respective contacts 118.

In the illustrated embodiment, at operation 204, liner layer 136 is formed on/in spacers 106, PEL 132, and cavities 134. Liner layer 136 comprises a different material than that of spacers 106 so that liner layer 136 is selectively etchable compared to spacers 106, as shown in FIG. 3B. In one embodiment, liner layer 136 can be comprised of SiC and spacers 106 are comprised of SiN.

In the illustrated embodiment, at operation 206, portions of liner layer 136 are removed from the nFET regions without removing spacers 106 due to the selectivity between spacer 106 and liner layer 136. As shown in FIG. 3C, nS/Ds 110 are formed on wafer 102.

In the illustrated embodiment, at operation 208, gates 104 are formed after removal of dummy gate material, and insulator layer 138 is formed on the current intermediary version of the semiconductor structure, as shown in FIG. 3D.

In the illustrated embodiment, at operation 210, mask 140 is applied to insulator layer 138, and portions of insulator layer 138, liner layer 136, and PEL 132 (labeled in FIG. 3A) are exposed and selectively removed to form canyons 142. As shown in FIG. 3E, this completes PEMs 120 (including recesses 130) and liner 116 (although some portions of liner layer 136 remain that are not parts of liner 116). It should be noted that operation 210 excludes work in the nFET regions. This is because n-doped epitaxial material (such as nS/Ds 110) can etch at a somewhat different rate from p-doped epitaxial material (such as pS/Ds 108). Furthermore, due to the previous operations in method 200, portions of liner layer 136 remain in the pFET regions that reduce the width of canyons 142. So, if canyons 142 were formed down to nS/Ds 110 at operation 210, and then canyons 142 were metalized immediately thereafter, the resulting contacts for pS/Ds 108 would be narrower than the resulting contacts for nS/Ds 110. This would create a distinct performance gap between the pFETs and the nFETs due to the increased electrical resistance of the pFETs. Therefore, it can be advantageous to etch down/into pS/Ds 108 in a separate step from etching down to nS/Ds 110, as is done in method 200.

In the illustrated embodiment, at operation 212, mask 140 is removed, and IEMs 122 are formed on liner 116, PEMs 120, liner layer 136, and insulator layer 138. As shown in FIG. 3F, this completes the formation of pS/Ds 108.

In the illustrated embodiment, at operation 214, mask 144 is applied to the current intermediary version of the semiconductor structure (including pS/Ds 108). As shown in FIG. 3G, portions of insulator layer 138 and spacers 106 are selectively removed to form canyons 146, expose nS/Ds 110, and finalize insulator 114. It should be noted that operation 214 excludes work in the pFET regions for the reasons explained above.

In the illustrated embodiment, at operation 216, mask 144 and the exposed remainder of liner layer 136 are removed, although liner 116 remains since it is covered by insulator 114 and IEM 122A. As shown in FIG. 3H, this exposes pS/Ds 108, including some of the top side of PEMs 120 and at least two of the opposing sides of IEMs 122.

In the illustrated embodiment, at operation 218, contacts 118 are formed in canyons 142 and 146 and on pS/Ds 108 and nS/Ds 110 to complete semiconductor structure 100 (although further processing may be performed in creation of an entire integrated circuit), as shown in FIG. 3I.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layers “C” and “D”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process operations described herein can be incorporated into a more comprehensive procedure or process having additional operations or functionality not described in detail herein. In particular, various operations in the manufacture of semiconductor devices and semiconductor-based ICs are well known and so, in the interest of brevity, many conventional operations will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition can be any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching can be any process that removes material from the wafer. Examples include etch processes (either wet or dry), chemical mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping can be the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography can be the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer operations are repeated multiple times. Each pattern being printed on the wafer is aligned to the previously formed patterns and gradually the conductors, insulators and selectively doped regions are built up to form the final device.

The following are non-exclusive descriptions of some example embodiments of the present disclosure.

A semiconductor structure, according to an example embodiment of this disclosure, among other possible things, includes: a wafer; a first source/drain (S/D) extending from the wafer; and a first contact connected to the first S/D. The first S/D includes: a first component in direct contact with the wafer and the first contact, the first component having a first germanium content; and a second component in direct contact with the first contact, the second component having a second germanium content. The second germanium content is higher than the first germanium content. Such an embodiment can provide the technical effect and/or advantage of reducing electrical contact resistance between the first contact and the first S/D, which can increase the performance of the semiconductor structure.

The semiconductor structure of the preceding paragraph can optionally include, additionally and/or alternatively, any one or more of the following features, configurations, and/or additional components.

In a further embodiment of the foregoing semiconductor structure, the first contact extends along two first opposing sides of the second component. Such an embodiment can provide the technical effect and/or advantage of increasing the surface area of contact between the first contact and the second component, which reduces electrical contact resistance therebetween.

In a further embodiment of any of the foregoing semiconductor structures, the first S/D extends along the two first opposing sides of the second component. Such an embodiment can provide the technical effect and/or advantage of increasing the surface area of contact between the first S/D and the second component, which reduces electrical contact resistance therebetween.

In a further embodiment of any of the foregoing semiconductor structures, the semiconductor structure further includes an electrically insulative liner extending along two second opposing sides of the first S/D. Such an embodiment can provide the technical effect and/or advantage of electrically insulating the first S/Ds from adjacent S/Ds.

In a further embodiment of any of the foregoing semiconductor structures, the first S/D is p-doped. Such an embodiment can provide the technical effect and/or advantage of reducing the performance gap that would otherwise exist between pFETs and nFETs.

In a further embodiment of any of the foregoing semiconductor structures, the semiconductor structure further includes a second S/D that extends form the wafer and is connected to a second contact, wherein the second S/D is monolithic. Such an embodiment can provide the technical effect and/or advantage of foregoing the extra operation(s) and material(s) used to create the first S/D.

In a further embodiment of any of the foregoing semiconductor structures, the second S/D has a solely planar interface with the second contact that lacks a recess. Such an embodiment can provide the technical effect and/or advantage of foregoing the extra operation(s) and material(s) used to create the first S/D.

In a further embodiment of any of the foregoing semiconductor structures, the first germanium content is in a range of 20% to 35%, and the second germanium content is in a range of 45% to 100%. Such an embodiment can provide the technical effect and/or advantage of including a higher germanium content that reduces electrical contact resistance with the first contact, and including a lower germanium content that allows for easier growth and patterning when compared to a higher germanium content.

A semiconductor structure, according to an example embodiment of this disclosure, among other possible things, includes: a wafer; a first source/drain (S/D) extending from the wafer; and a first contact connected to the first S/D. The first S/D includes: a first component in direct contact with the wafer and the first contact; and a second component in direct contact with the first contact. The first contact extends along two first opposing sides of the second component. Such an embodiment can provide the technical effect and/or advantage of increasing the surface area of contact between the first contact and the first S/D, which can reduce electrical contact resistance and increase the performance of the semiconductor structure.

The semiconductor structure of the preceding paragraph can optionally include, additionally and/or alternatively, any one or more of the following features, configurations, and/or additional components.

In a further embodiment of the foregoing semiconductor structure, the first S/D extends along the two first opposing sides of the second component. Such an embodiment can provide the technical effect and/or advantage of increasing the surface area of contact between the first S/D and the second component, which reduces electrical contact resistance therebetween.

In a further embodiment of any of the foregoing semiconductor structures, the semiconductor structure further includes an electrically insulative liner extending along two second opposing sides of the first S/D. Such an embodiment can provide the technical effect and/or advantage of electrically insulating the first S/Ds from adjacent S/Ds.

In a further embodiment of any of the foregoing semiconductor structures, the semiconductor structure further includes a second S/D that extends from the wafer and is connected to a second contact, wherein the second S/D lacks the electrically insulative liner. Such an embodiment can provide the technical effect and/or advantage of foregoing the extra operation(s) and material(s) used to create the electrically insulative liner.

In a further embodiment of any of the foregoing semiconductor structures, the semiconductor structure further includes two electrically insulative spacers that extend along two third opposing sides of the first S/D that are different from the two second opposing sides of the first S/D, wherein the spacers are comprised of a different material from the liner. Such an embodiment can provide the technical effect and/or advantage of allowing portions of the liner to be removed to increase the size of the first contact while still electrically insulating the first contact.

In a further embodiment of any of the foregoing semiconductor structures, the first S/D is p-doped. Such an embodiment can provide the technical effect and/or advantage of reducing the performance gap that would otherwise exist between pFETs and nFETs.

In a further embodiment of any of the foregoing semiconductor structures, the semiconductor structure further includes a second S/D that extends from the wafer and is connected to a second contact, wherein the second S/D is monolithic. Such an embodiment can provide the technical effect and/or advantage of foregoing the extra operation(s) and material(s) used to create the first S/D.

In a further embodiment of any of the foregoing semiconductor structures, the first component has a first germanium content; the second component has a second germanium content; and the second germanium content is higher than the first germanium content. Such an embodiment can provide the technical effect and/or advantage of reducing electrical contact resistance between the first contact and the first S/D, which can increase the performance of the semiconductor structure.

In a further embodiment of any of the foregoing semiconductor structures, the first germanium content is in a range of 20% to 35%, and the second germanium content is in a range of 45% to 100%. Such an embodiment can provide the technical effect and/or advantage of including a higher germanium content that reduces electrical contact resistance with the first contact, and including a lower germanium content that allows for easier growth and patterning when compared to a higher germanium content.

A method of manufacturing a semiconductor structure, according to an example embodiment of this disclosure, among other possible things, includes: providing an intermediary semiconductor structure including: a plurality of spacers; and a first component of a first source/drain (S/D) in direct contact with two of the plurality of spacers; forming a liner layer on the plurality of spacers and on the first S/D; removing a portion of the liner layer in a region for a second S/D; forming the second S/D; forming an insulator layer on a remaining portion of the liner layer and on the second S/D; forming a first canyon to expose the first component; forming a second component of the first S/D on the first component; forming a second canyon to expose the second S/D; removing an exposed portion of the liner layer while a covered portion of the liner layer remains; and forming a first electrically conductive contact in the first canyon and a second electrically conductive contact in the second canyon. Such an embodiment can provide the technical effect and/or advantage of creating the first S/D separately from creating the second S/D, which allows for better control since the first S/D is doped differently from the second S/D.

The method of the preceding paragraph can optionally include, additionally and/or alternatively, any one or more of the following features, configurations, and/or additional components.

In a further embodiment of the foregoing method, a first germanium content of the first component is lower than a second germanium content of the second component. Such an embodiment can provide the technical effect and/or advantage of reducing electrical contact resistance between the first contact and the first S/D, which can increase the performance of the semiconductor structure.

In a further embodiment of any of the foregoing methods, the first electrically conductive contact extends along two opposing sides of the second component; and the first component extends along the two opposing sides of the second component. Such an embodiment can provide the technical effect and/or advantage of increasing the surface area of contact between the first contact and the second component, which reduces electrical contact resistance therebetween.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a wafer;
a first source/drain (S/D) extending from the wafer; and
a first contact connected to the first S/D;
wherein the first S/D comprises:
a first component in direct contact with the wafer and the first contact, the first component having a first germanium content; and
a second component in direct contact with the first contact, the second component having a second germanium content;
wherein the second germanium content is higher than the first germanium content.

2. The semiconductor structure of claim 1, wherein the first contact extends along two first opposing sides of the second component.

3. The semiconductor structure of claim 2, wherein the first S/D extends along the two first opposing sides of the second component.

4. The semiconductor structure of claim 1, further comprising an electrically insulative liner extending along two second opposing sides of the first S/D.

5. The semiconductor structure of claim 1, wherein the first S/D is p-doped.

6. The semiconductor structure of claim 1, further comprising a second S/D that extends form the wafer and is connected to a second contact, wherein the second S/D is monolithic.

7. The semiconductor structure of claim 6, wherein the second S/D has an interface with the second contact that lacks a recess.

8. The semiconductor structure of claim 1, wherein the first germanium content is in a range of 20% to 35%, and the second germanium content is in a range of 45% to 100%.

9. A semiconductor structure comprising:
a wafer;
a first source/drain (S/D) extending from the wafer; and
a first contact connected to the first S/D;
wherein the first S/D comprises:
a first component in direct contact with the wafer and the first contact; and
a second component in direct contact with the first contact;
wherein the first contact extends along two first opposing sides of the second component.

10. The semiconductor structure of claim 9, wherein the first S/D extends along the two first opposing sides of the second component.

11. The semiconductor structure of claim 9, further comprising an electrically insulative liner extending along two second opposing sides of the first S/D.

12. The semiconductor structure of claim 11, further comprising a second S/D that extends from the wafer and is connected to a second contact, wherein the second S/D lacks the electrically insulative liner.

13. The semiconductor structure of claim 11, further comprising two electrically insulative spacers that extend along two third opposing sides of the first S/D that are different from the two second opposing sides of the first S/D, wherein the spacers are comprised of a different material from the liner.

14. The semiconductor structure of claim 9, wherein the first S/D is p-doped.

15. The semiconductor structure of claim 9, further comprising a second S/D that extends from the wafer and is connected to a second contact, wherein the second S/D is monolithic.

16. The semiconductor structure of claim 9, wherein:
the first component has a first germanium content;
the second component has a second germanium content; and
the second germanium content is higher than the first germanium content.

17. The semiconductor structure of claim 16, wherein the first germanium content is in a range of 20% to 35%, and the second germanium content is in a range of 45% to 100%.

18. A method of manufacturing a semiconductor structure comprises:
providing an intermediary semiconductor structure comprising:
a plurality of spacers; and
a first component of a first source/drain (S/D) in direct contact with two of the plurality of spacers;
forming a liner layer on the plurality of spacers and on the first S/D;
removing a portion of the liner layer in a region for a second S/D;
forming the second S/D;
forming an insulator layer on a remaining portion of the liner layer and on the second S/D;
forming a first canyon to expose the first component;
forming a second component of the first S/D on the first component;
forming a second canyon to expose the second S/D;
removing an exposed portion of the liner layer while a covered portion of the liner layer remains; and
forming a first electrically conductive contact in the first canyon and a second electrically conductive contact in the second canyon.

19. The method of claim 18, wherein a first germanium content of the first component is lower than a second germanium content of the second component.

20. The method of claim 18, wherein:
the first electrically conductive contact extends along two opposing sides of the second component; and
the first component extends along the two opposing sides of the second component.
